(19) United States
(12) Patent Application Publication
(10) Pub. No.: US 2020/0058474 A1
(43) Pub. Date: Feb. 20, 2020

(54) WATER MOLECULE SUPPLY DEVICE FOR PLASMA TORCH EXCITATION DEVICE

(71) Applicant: Orient Service Co., Ltd., Taipei (TW)

(72) Inventor: WU-YU FONG, TAIPEI (TW)

(21) Appl. No.: 16/145,944

(22) Filed: Sep. 28, 2018

(30) Foreign Application Priority Data
Aug. 15, 2018 (TW) 107128479

(51) Int. Cl. H01J 37/32

(52) U.S. Cl. CPC H01J 37/32844; H01J 37/32541; H01J 2237/327; H01J 37/32449; H01J 37/32568

(57) ABSTRACT

A water molecule supply device for a plasma torch excitation device, comprising a flame outlet end formed at a bottom end of a plasma torch excitation device. The plasma torch excitation device has a water cavity therein, and the flame outlet end is fixed and provided with a mask body having a flame channel through which the plasma torch is ejected. A plurality of water guiding holes surrounding the flame channel are formed in the mask body, and the plurality of water guiding holes are respectively connected between the water cavity and the flame channel. The water molecules are supplied from the flame channel to be ejected so that water molecules contact the torch flame in the flame channel to capture the F₂ gas so as to react into hydrogen fluoride (HF) which is more easily subjected to water washing filtration.

### FIELD OF THE INVENTION

The present invention relates to a technique for capturing a product after a semiconductor process exhaust gas is subjected to a sintering reaction by a plasma torch (Plasma Torch), and more particularly to a water molecule supply device for a plasma torch excitation device.

### DESCRIPTION OF RELATED ART

It is known that the exhaust gas generated by the semiconductor process comprises SiH₄, H₂SiCl₂ (DCS), WF₆, BF₃, NF₃, SF₆, CF₄, C₂F₆, C₃F₈, etc., among which NF₃, SF₆, CF₄, C₂F₆ and C₃F₈ belong to harmful fluoride (Per Fluorinated Compounds, PFC), if discharged into the atmosphere, they cause environmental pollution and even exert the greenhouse effect, which has a serious impact on global warming, so these exhaust gases must be treated into harmless gases.

The semiconductor exhaust gas treatment equipment widely used in the workshop is used to treat the above-mentioned exhaust gas into a harmless gas. In general, well-known semiconductor exhaust gas treatment devices are provided with a reaction compartment of exhaust gas, and exhaust gas generated by the semiconductor process is introduced into the reaction compartment and sintered by a high temperature gas flame, a hot rod or a plasma torch flame in the reaction compartment. The sintering reaction is used to sinter the exhaust gas (i.e., the sintering reaction), in particular, a high-temperature sintering reaction, can decompose fluoride gases, such as NF₃, SF₆, CF₄, C₂F₆, and C₃F₈, into harmless fluoride ions (F), in order to achieve the purpose of purifying the exhaust gas.

The above-mentioned plasma torch is a high-temperature flame capable of generating a beam of directed plasma jets. The temperature of the torch flame can be as high as 3000° C.-10000° C., so that it is commonly used in material processing, welding, waste treatment, ceramics, metal cutting and semiconductor exhaust gas sintering.

It is also known that after the exhaust gas is subjected to high-temperature sintering treatment by a gas flame, a hot rod or a plasma torch flame, the F₂ gas and other products are generated in the reaction compartment. The products are usually subjected to a subsequent scrubbing procedure. The product is captured and scrubbed so that the above product can be deposited in water and filtered.

However, since the molecular size of the F₂ gas is extremely small, the water washing program used in the known semiconductor exhaust gas treating equipment does not sufficiently capture the above-mentioned F₂ gas, which causes the purification efficiency of the semiconductor process exhaust gas to be ineffective, so that there is a manufacturer who deliberately supply water (H₂O) into the reaction compartment, and to dissociate water molecules contained in water (H₂O) into hydrogen ions (H⁺) and hydroxide ions by virtue of the above-mentioned high temperature gas flame, a hot rod or an plasma torch flame (OH⁺). To use hydrogen ions (H⁺) in combination with F₂ gas to form hydrogen fluoride (HF) which is easily soluble in water facilitates the capture and scrubbing of the subsequent water washing program. However, in the reaction compartment of the existing semiconductor exhaust gas treatment equipment, the chamber and space structure in which the water molecules are in contact with the gas flame, the hot rod or the torch flame are not ideal. It is difficult for the water molecules to instantaneously capture the F₂ gas. After the exhaust gas is sintered by plasma torch flame, the F₂ gas is formed into hydrogen fluoride (HF), which even affects the purification efficiency of harmful substances in the exhaust gas, so it needs to be improved.

### SUMMARY OF THE INVENTION

In view of this, the main object of the present invention is to improve the problem of insufficient supply of sufficient water molecules around the conventional torch flame to affect the capture efficiency of the F₂ gas, and to provide a water molecule supply device for the plasma torch excitation device.

In a preferred embodiment of the present invention, the technical means of the present invention is to provide a water molecule supply device for a plasma torch excitation device comprising:

a flame outlet end formed at a bottom end of the plasma torch excitation device, the plasma torch excitation device comprising an electrode and an electrode housing having a conical core bore for use as an electric field of charged ions, the electrode projecting charged ions to generate a plasma torch flame in the core bore, and the plasma torch flame being ejected from the flame outlet end;

a water cavity is formed around the electrode housing, and the water cavity guiding water into a loop in the water cavity through an inlet pipe and an outlet pipe, and the outer wall of the electrode housing being formed into a fin shape to contact the water in the loop in the water cavity; and

a mask body fixed on the flame outlet end, the mask body having a flame channel for providing a plasma torch to eject, and the mask body being provided with a plurality of water guiding holes surrounding the flame channel, and the plurality of water guiding holes being respectively connected between the water cavity and the flame channel, water molecules being ejected from the flame channel to cause water molecules to contact the plasma torch flame in the flame channel.

In a further implementation of the present invention, preferably a periphery of the flame channel is formed as a conical bore wall, and the plurality of water guiding holes supply water molecules from the conical bore wall to the flame channel to be ejected. The plurality of water guiding holes respectively are in communication with water outlet holes formed on the wall of the conical bore wall, and the plurality of water guiding holes respectively supply water molecules to the flame channels through the respective water outlet holes. Each of the water outlet holes has a hole line, the flame channel has an axis line and an angle between the hole line and the axis line is 0<the angle<90°. The total water output of each of the water outlet holes is smaller than the water discharge amount of the water outlet pipe, and the water inlet of the water inlet pipe is larger than the amount of water of the water outlet pipe.

In a further implementation of the present invention, preferably the mask body has a top surface and a bottom surface, and the conical bore wall of the flame channel is gradually expanded from the top surface to the bottom surface to be formed.

In a further implementation of the present invention, preferably a peripheral of the electrode housing is provided with an electrode core seat, the water cavity is formed on the electrode housing and the electrode core seat, and the water inlet pipe and the water outlet pipe are respectively disposed on the electrode core seat to communicate with the water cavity.

In a further implementation of the present invention, preferably the plasma torch excitation device further comprises a electrode core frame, the electrode core frame has a hollow chamber, the electrode housing is arranging on a top portion of the electrode core frame, one of the electrodes for projecting the charged ions is used for implanting in the chamber to form a gas connecting conduit surrounding the electrode and the wall of the chamber, the electrode housing is fixed to the bottom of the electrode core frame, and the core bore communicates with the gas connecting conduit, and the electric ion projecting end is adjacent to the core bore.

In a further implementation of the present invention, preferably the plasma torch excitation device is disposed on a semiconductor waste gas treatment tank, and a reaction compartment is formed in the semiconductor waste gas treatment tank, the flame outlet end of the plasma torch excitation device is implanted in the reaction compartment.

According to the above technology, the technical effects that can be produced by the present invention are as follows:
1. The water outlet hole is disposed around the flame channel, so that the water molecules sprayed from the water guiding hole or the water outlet hole can be concentrated around the flame of the plasma torch, so that the water molecules can immediately contact the flame of the plasma torch and receive the flame of the plasma torch to be dissociated into hydrogen ions (H⁺) and hydroxide ions (OH⁺), allowing hydrogen ions (H⁺) to rapidly combine with F₂ gas generated after sintering of exhaust gas into hydrogen fluoride (HF) that is easily soluble in water to promote the purification efficiency of the harmful substance in the waste gases.
2. Since the water molecules ejected from the water outlet hole are supplied by the water cavity used to cool the electrode housing in the water cavity, there is no need to additionally add a pipeline for water supply so that the structure of the water molecule supply device is simplified.
3. By the structural design of the conical bore wall of the flame channel, and the water guiding hole or the water outlet hole for supplying water molecules are connected or formed on the conical bore wall, so that the plasma torch flame emitted from the flame outlet end can be in rapid contact with the water molecules during the flame protection process of the conical bore wall.

The specific implementation details of the above technical means and their production performance will be described with reference to the following embodiments and drawings.

### BRIEF DESCRIPTION OF THE DRAWINGS

FIG. 1 is a cross-sectional view showing a water molecule supply device of a plasma torch excitation device of the present invention;

FIG. 2 is a cross-sectional view taken along line A-A of FIG. 1 of the present invention;

FIG. 3 is a schematic view of the movement operation of FIG. 1 of the present invention;

FIG. 4 is a cross-sectional view showing the water molecule supply device of the torch excitation device of the present invention disposed in an exhaust gas treatment tank.

### DETAILED DESCRIPTION OF THE PREFERRED EMBODIMENT

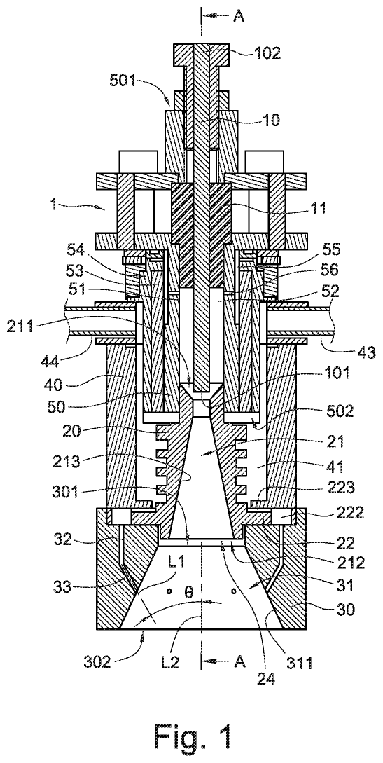

First, referring to FIG. 1 illustrating a preferred embodiment of a water molecule supply device for a plasma torch excitation device according to the present invention. The water molecule supply device comprises a flame outlet end 24, a water cavity 41 and a mask body 30.

The flame outlet end 24 is formed at the bottom end of the plasma torch excitation device 1. The plasma torch excitation device 1 comprises an electrode 10 and an electrode housing 20 in implementation. The electrode 10 is made of a conductive metal rod shape so that the electrode 10 has an electric ion projecting end 101 and a connecting terminal 102. The electrode housing 20 is made of a conductive metal having a conical core bore 21 for use as an electric field of charged ions, and the electric ion projecting end 101 of the electrode 10 projects charged ions in the core bore 21 to generate a plasma torch flame. Further, the core bore 21 has an inner end 211 and an outer end 212. The core bore 21 is gradually expanded from the inner end 211 to the outer end 212 to have a conical shape. In practice, the electric ion projecting end 101 of the electrode 10 is adjacent to the inner end 211 of the core bore 21. The torch flame is ejected from the outer end 212 of the core bore 21, in other words, the flame outlet end 24 is referred to as the outer end 212 of core bore 21.

The water cavity 41 is formed around the electrode housing 20. The water cavity 41 guides flowing water through a flowing loop in the water cavity 41 via an inlet pipe 43 and an outlet pipe 44 to cool the temperature of the electrode housing 20. The outer wall of the electrode housing 20 is formed in a fin shape, and the fin-shaped outer wall can increase the contact area of the electrode housing 20 with the flowing loop water in the water cavity 41, thereby increasing the heating exchange effect of the water for cooling electrode housing 20.

The mask body 30 is fixed to the flame outlet end 24 to allow the plasma torch flame to be ejected through the mask body 30. The mask body 30 is made of a heat-resistant metal into a ring shape, and the mask body 30 has a top surface 301 and a bottom surface 302 in a toroidal shape. The mask body 30 has a flame channel 31 extending from the top surface 301 to the bottom surface 302. The plasma torch flame is ejected through the mask body 30 via the flame channel 31. A plurality of water guiding holes 32 surrounding the flame channel 31 are defined in the mask body 30. One end of the plurality of water guiding holes 32 extends to the top surface 301 of the mask body 30. The plurality of water guiding holes 32 are used respectively to connect between the water cavity 41 and the flame channel 31, the water in the water cavity 41 passes through the water guiding hole 32 and is ejected from the flame channel 31 in the form of aerosolized water molecules, and the aerosol is formed. The aerosolized water molecules are in contact with the plasma torch flame in the flame channel 31 through the guiding of the water guiding hole 32 so that the plasma torch flame decomposes the aerosolized water molecules into hydrogen ions (H⁺) and hydroxide ions (OH⁺).

Further, the periphery of the flame channel 31 in the mask body 30 is formed as a conical bore wall 311 which is formed in the center of the toroidal top surface 301 and the bottom surface 302. The conical bore wall 311 is formed by gradually expanding the top surface 301 to the bottom surface 302. A water outlet hole 33 is formed in the conical bore wall 311 to communicate with the plurality of water guiding holes 32. The water in the water cavity 41 is sequentially passed through the water guiding hole 32 and the water outlet hole 33 to be aerosolized so that the water molecules in aerosolized state is ejected from the flame channel 31. In a specific implementation, the total water output of each of the water outlet holes 33 is smaller than the water discharge amount of the water outlet pipe 44, and the water discharge amount of the water outlet pipe 44 is larger than the water inlet amount of the water inlet pipe 43, so that the water in the water cavity 41 is pressurized so that the water in the water cavity 41 passes through the water outlet hole 33 and is ejected in the form of aerosol-like water molecules. Further, each of the water outlet holes 33 has a hole line L1, and the flame channel 31 has an axis line L2, and the hole line L1 has an angle θ with the axis line L2. The angle θ is greater than 0 degrees and less than 90 degrees, that is, 0<θ<90°, so that aerosol-like water molecules can be ejected from the water outlet holes 33 toward the plasma torch flame in the flame channel 31. It is advantageous for the aerosol-like water molecules to contact the plasma torch flame. Further, the conical bore wall 311 of the flame channel 31 can form a flameproof effect on the plasma torch flame ejected by the core bore 21 (that is, the flame outlet end 24).

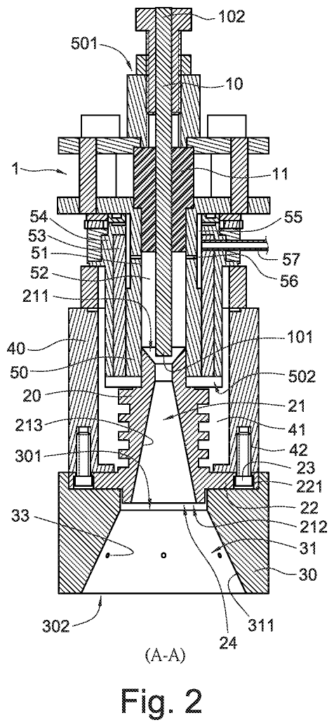

Referring to FIG. 1 and FIG. 2 together, the peripheral of the electrode housing 20 is provided with an electrode core seat 40. The water cavity 41 is formed between the electrode housing 20 and the electrode core seat 40. The water inlet pipe 43 and the water outlet pipe 44 in communicate with the water cavity 41 are respectively disposed on the electrode core seat 40 so that water can flow into the water cavity 41 from the water inlet pipe 43, and then flow out from the water outlet pipe 44 to form a water loop to cool the temperature of the electrode housing 20. Further, the electrode core seat 40 is formed with a plurality of screw holes 42. The outer wall of the electrode housing 20 is formed with a ring portion 22, and the ring portion 22 is provided with fixing hole 221 corresponding to the plurality of threaded holes 42. The fixing hole 221 is screwed to the threaded hole 42 through the fixing hole 221 by the screw 23 so that the electrode housing 20 and the electrode core seat 40 are fixedly coupled to each other.

Referring to FIG. 1. The ring portion 22 of the electrode housing 20 is further provided with a plurality of the diversion holes 222 surrounding the periphery of the top surface 301, and the ring portion 22 is further formed with a plurality of the diversion grooves 223 in communication with the diversion holes 222 allows water in the water cavity 41 to flow into the diversion hole 222 via the diversion groove 223. The diversion holes 222 are respectively the water guiding holes 32 corresponding to the mask body 30 in implementation. When the mask body 30 is fixed to the flame outlet end 24, the diversion holes 222 are respectively in communication with the corresponding water guiding holes 32 such that water in the water cavity 41 is sequentially ejected from the flame channel 31 via the diversion grooves 223, the diversion holes 222, the water guiding holes 32 and the water outlet holes 33. In addition to being used to cool the electrode housing 20, the water in the water cavity 41 can flow into the water guiding hole 32 and is ejected from the water outlet hole 33, so that no additional piping for water supply is required, thereby simplifying the structure of the device for the supply of water molecules of the present invention.

Referring to FIG. 1, the plasma torch excitation device 1 further comprises an electrode core frame 50. The electrode core frame 50 is roughly formed into a seat tube shape, and the electrode core frame 50 has a hollow chamber 51. The electrode 10 is fixed to the top portion 501 of the electrode core frame 50 via a centering of an insulating sleeve 11, and enables the electric ion projecting end 101 of the electrode 10 to be implanted in the chamber 51 to form a gas connecting conduit 52 surrounding the periphery wall of the electrode 10 and the chamber 51. The connecting terminal 102 of the electrode 10 protrudes from the electrode core frame 50 to connect to the power source. Further, the electrode housing 20 is fixed to the bottom portion 502 of the electrode core frame 50, and the inner end 211 of the core bore 21 communicates with the gas connecting conduit 52. The electrode core seat 40 is fixed to the bottom portion 502 of the electrode core frame 50 via a bearing seat 54 and is then covered around the electrode housing 20.

Referring to FIG. 2, the periphery of the electrode core frame 50 is provided with a bearing sleeve 53 to form an annular gas guiding groove 55 between the electrode core frame 50 and the bearing sleeve 53. On the wall of the chamber 51 of the electrode core frame 50, a plurality of gas guiding bores 56 that communicate with the gas connecting conduit 52 and the annular gas guiding groove 55 are formed. In other words, an air flow path is formed between the annular gas guiding groove 55, the gas guiding bore 56 and the gas connecting conduit 52. The annular gas guiding groove 55 is in communication with an gas inlet pipe 57 for introducing a gas such as He, Ar, N₂ or O₂, such that the gas is flowing along an air flow passage formed between the annular gas guiding groove 55, the gas guiding bore 56 and the gas connecting conduit 52 to flow toward the core bore 21 and then flows out through the core bore 21.

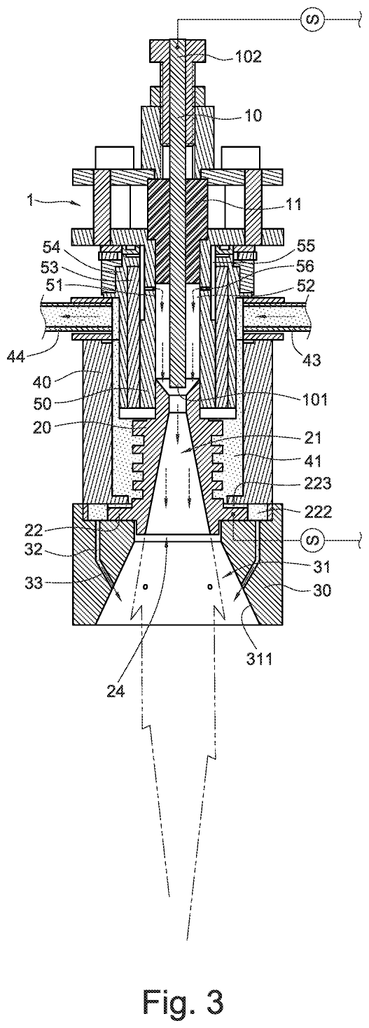

Referring to FIG. 3, the positive pole and the negative pole of the power source are respectively connected to the connecting terminal 102 of the electrode 10 and the electrode housing 20 to be energized, and the electrode 10 is excited between the electrode 10 and the bore wall 213 of the core bore 21 to generate the collision and the bounce of electric ions (e−) to cause the inside of the core bore 21 to be an electric field for generating electric ions (e−), and at the same time, it introduces the gas set such as He, Ar, N₂ or O₂ in the gas connecting conduit 52. By pressing, the electric ions (e−) are pushed out from the outer end 212 of the core bore 21 via the gas, thereby forming a plasma torch flame of the external jet, which is passed through the flame channel 31 when the plasma flame torch passes through the flame channel 31. The conical bore wall 311 is configured to form a flame-proof effect on the plasma torch flame ejected by the core bore 21. In this state, the temperature of the electrode housing 20 can be lowered by the circulating water flowing from the water inlet pipe 43 into the water cavity 41 and then flowing out of the water outlet pipe 44, thereby preventing the electrode housing 20 from being heated by the plasma torch flame. The durable service life is increased, in particular, the outer wall of the fin-shaped electrode housing 20 provides a large heat exchange area, which facilitates heat exchange with water in the water cavity 41, and can effectively avoid the temperature of electrode housing 20 is too high. Further, the portion of the loop water flowing into the water cavity 41 from the inlet pipe 43 flows into the diversion hole 222 through the diversion groove 223, and is discharged outward through the water guiding hole 32 and the water outlet hole 33, and is ejected by the water outlet hole 33. The aerosol-like water molecules are decomposed into hydrogen ions (H⁺) and hydroxide ions (OH⁺) by the pyrolysis of the plasma torch flame emitted from the core bore 21.

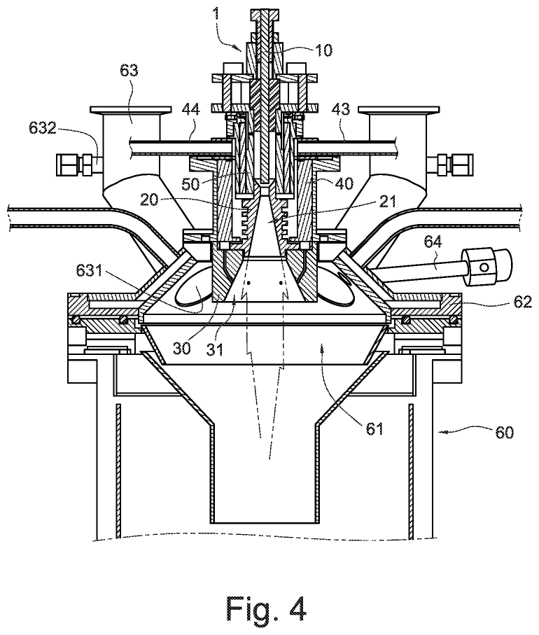

Referring to FIG. 4, the plasma torch excitation device 1 of the present invention is disposed on a semiconductor waste gas treatment tank 60. A reaction compartment 61 is formed in the semiconductor waste gas treatment tank 60, and the semiconductor process exhaust gas is first introduced into the reaction compartment 61. The sintering process is then carried out at the high temperature provided by the plasma torch. Further, the top cover of the semiconductor waste gas treatment tank 60 is provided with a head cover 62. The electrode core seat 40 is disposed on the head cover 62 to implant the flame outlet end 24 of the plasma torch excitation device 1 into the reaction compartment 61. The plasma torch flame formed by the jet flow of the core bore 21 of the electrode housing 20 enters the reaction compartment 61 to sinter the semiconductor process exhaust gas, and the semiconductor process exhaust gas can be, for example, after a high-temperature sintering reaction, harmful NF₃, SF₆, CF₄, C₂F₆, and C₃F₈ and other Fluorinated Compounds (PFC) gases which are decomposed into harmless fluoride ions and fluoride ions, and aerosolized water molecules are decomposed by the high temperature of the plasma torch flame to obtain the ion (H⁺) such that the fluoride ions and fluoride ions combine to form hydrogen fluoride. Since the hydrogen fluoride is easily soluble in water, it is advantageous for the capture and scrubbing of the subsequent water washing program to purify the exhaust gas.

The semiconductor waste gas treatment tank 60 is configured to have at least one exhaust gas introduction pipe 63 of a semiconductor process exhaust gas, and an end of the exhaust gas introduction pipe 63 is implanted in the reaction compartment 61 is formed with an exit 631 through which the exhaust gas introduction pipe 63 passes. The exhaust gas introduction pipe 63 is in communication with the reaction compartment 61 via the exit 631, and the exhaust gas introduction pipe 63 guides the semiconductor process exhaust gas into the reaction compartment 61. Further, the exhaust gas introduction pipe 63 and the electrode core frame 50 are disposed at intervals on the head cover 62, so that the exhaust gas introduction pipe 63 can guide the exhaust gas into the reaction compartment 61 from the top portion of the semiconductor waste gas treatment tank 60. In addition, the exhaust gas introduction pipe 63 is provided with an intake pressure detecting port 632. The intake pressure detecting port 632 can detect the pressure and flowing amount of the semiconductor process exhaust gas flowing into the reaction compartment 61 in the exhaust gas introducing pipe 63 by using an instrument. The head cover 62 is further provided with an ultraviolet detecting port 64. The ultraviolet detecting port 64 can detect the working condition of the plasma torch by the ultraviolet detecting device.

The above description is intended to be illustrative, and not restrictive, and many modifications, variations or equivalents may be made without departing from the spirit and scope of the invention. All will fall within the scope of protection of the present invention.

We claim:

1. A water molecule supply device for a plasma torch excitation device comprising:
a flame outlet end formed at a bottom end of the plasma torch excitation device, the plasma torch excitation device comprising an electrode and an electrode housing having a conical core bore for use as an electric field of charged ions, the electrode projecting charged ions to generate a plasma torch flame in the core bore, and the plasma torch flame being ejected from the flame outlet end;
a water cavity is formed around the electrode housing, and the water cavity guiding water into a loop in the water cavity through an inlet pipe and an outlet pipe, and the outer wall of the electrode housing being formed into a fin shape to contact the water in the loop in the water cavity; and
a mask body fixed on the flame outlet end, the mask body having a flame channel for providing a plasma torch to eject, and the mask body being provided with a plurality of water guiding holes surrounding the flame channel, and the plurality of water guiding holes being respectively connected between the water cavity and the flame channel, water molecules being ejected from the flame channel to cause water molecules to contact the plasma torch flame in the flame channel.

2. The water molecule supply device of a plasma torch excitation device as claimed in claim 1, wherein a periphery of the flame channel is formed as a conical bore wall, and the plurality of water guiding holes supply water molecules from the conical bore wall to the flame channel to be ejected.

3. The water molecule supply device of the plasma torch excitation device as claimed in claim 2, wherein the plurality of water guiding holes respectively are in communication with water outlet holes formed on the wall of the conical bore wall, and the plurality of water guiding holes respectively supply water molecules to the flame channels through the respective water outlet holes.

4. The water molecule supply device of the plasma torch excitation device as claimed in claim 3, wherein each of the water outlet holes has a hole line, the flame channel has an axis line and an angle between the hole line and the axis line is 0<the angle<90°.

5. The water molecule supply device of the plasma torch excitation device as claimed in claim 3, wherein the total water output of each of the water outlet holes is smaller than the water discharge amount of the water outlet pipe, and the water inlet of the water inlet pipe is larger than the amount of water of the water outlet pipe.

6. The water molecule supply device of the plasma torch excitation device as claimed in claim 2, wherein the mask body has a top surface and a bottom surface, and the conical bore wall of the flame channel is gradually expanded from the top surface to the bottom surface to be formed.

7. The water molecule supply device of the plasma torch excitation device as claimed in claim 1, wherein a peripheral of the electrode housing is provided with an electrode core seat, the water cavity is formed on the electrode housing and the electrode core seat, and the water inlet pipe and the water outlet pipe are respectively disposed on the electrode core seat to communicate with the water cavity.

8. The water molecule supply device of the plasma torch excitation device as claimed in claim 1, wherein the plasma torch excitation device further comprises a electrode core frame, the electrode core frame has a hollow chamber, the electrode housing is arranging on a top portion of the electrode core frame, one of the electrodes for projecting the charged ions is used for implanting in the chamber to form a gas connecting conduit surrounding the electrode and the wall of the chamber, the electrode housing is fixed to the bottom of the electrode core frame, and the core bore communicates with the gas connecting conduit, and the electric ion projecting end is adjacent to the core bore.

9. The water molecule supply device of the plasma torch excitation device as claimed in claim 1, wherein the plasma torch excitation device is disposed on a semiconductor waste gas treatment tank, and a reaction compartment is formed in the semiconductor waste gas treatment tank, the flame outlet end of the plasma torch excitation device is implanted in the reaction compartment.
